(19) United States
(12) Patent Application Publication
(10) Pub. No.: US 2014/0290752 A1
(43) Pub. Date: Oct. 2, 2014

(54) PROCESSING METHOD AND PROCESSING APPARATUS

(71) Applicant: Tokyo Electron Limited, Tokyo (JP)

(72) Inventors: Hiroyuki Matsuura, Iwate (JP); Nobuyuki Hirota, Iwate (JP); Makoto Takado, Iwate (JP)

(73) Assignee: Tokyo Electron Limited, Tokyo (JP)

(21) Appl. No.: 14/225,617

(22) Filed: Mar. 26, 2014

(30) Foreign Application Priority Data
Mar. 28, 2013 (JP) 2013-070012

(51) Int. Cl. H01L 21/673

(52) U.S. Cl. CPC H01L 21/67389
USPC 137/14; 137/596

(57) ABSTRACT

A processing method is provided in which an object to be processed is processed within a processing container connected to a gas supply system, an exhaust system and an opening degree variable valve by using a processing gas in a plurality of sequential processing steps. The processing method includes: an acquisition process for acquiring an opening degree of the opening degree variable valve corresponding to a target pressure value within the processing container under a predetermined processing condition for at least one of the plurality of sequential processing steps; and an execution process for executing the at least one of the plurality of sequential processing steps for which the opening degree has been acquired by the acquisition process with the opening degree.

### CROSS-REFERENCE TO RELATED APPLICATIONS

This application is based on and claims priority from Japanese Patent Application No. 2013-070012, filed on Mar. 28, 2013, with the Japan Patent Office, the disclosure of which is incorporated herein in its entirety by reference.

### TECHNICAL FIELD

The present disclosure relates to a processing method and a processing apparatus.

### BACKGROUND

In manufacturing a semiconductor device, processes such as, for example, a deposition process, an oxidation process, a diffusion process, an annealing process, and an etching process are performed on a semiconductor wafer which is an object to be processed.

A processing apparatus configured to perform each process generally has a processing container connected to a gas supply system and a vacuum exhaust system, and may perform a predetermined process on semiconductor wafers accommodated within the processing container at a predetermined temperature, pressure and gas atmosphere.

In the pressure control inside the processing container, a conductance control device called an auto pressure controller (APC) is generally used. The APC is a pressure control device which sets an optimum operation table from, for example, flow rates of an inflow gas and an exhaust gas, and performs pressure control inside the processing container by the PID control method using the operation table. Here, the pressure within the processing container where objects to be processed are placed is controlled by a closed loop system in which information of a pressure gauge is fed back to obtain a predetermined pressure while an opening degree of a pressure control valve is automatically adjusted. See. e.g., Japanese Patent Application Laid-Open No. 2011-44446.

### SUMMARY

The present disclosure provides a processing method that processes an object to be processed within a processing container connected to a gas supply system, an exhaust system and an opening degree variable valve by using a processing gas in a plurality of sequential processing steps. The processing method includes: an acquisition process for acquiring an opening degree of the opening degree variable valve corresponding to a target pressure value within the processing container under a predetermined processing condition for at least one of the plurality of sequential processing steps; and an execution process for executing the at least one of the plurality of sequential processing steps for which the opening degree has been acquired by the acquisition process with the opening degree.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 illustrates a schematic configuration view of a processing apparatus according to an exemplary embodiment of the present disclosure.

FIG. 2 illustrates a schematic configuration view of a vicinity of a processing container of the processing apparatus of FIG. 1.

FIG. 3 illustrates a schematic configuration view of the vicinity of an opening degree variable valve of the processing apparatus of FIG. 1.

FIG. 4 illustrates a flow chart of a processing method according to an exemplary embodiment of the present disclosure.

FIG. 5 illustrates a schematic view for explaining the processing method according to the present disclosure.

FIG. 6 illustrates a schematic view for explaining an acquisition process according to the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In a method of controlling the pressure within a processing container by using a PID control method, a relatively long time is required until the pressure within the processing container converges on a required pressure value or on a required pressure range.

In relation to the above described problem, the present disclosure provides a processing method which may allow the pressure within the processing container to reach a required pressure value or a required pressure range within a short time.

An aspect of the present disclosure is to provide a processing method that processes an object to be processed within a processing container connected to a gas supply system, an exhaust system and an opening degree variable valve by using a processing gas in a plurality of sequential processing steps. The processing method includes: acquiring an opening degree of the opening degree variable valve corresponding to a target pressure value within the processing container under a predetermined processing condition for at least one of the plurality of sequential processing steps; and executing the at least one of the plurality of sequential processing steps for which the opening degree has been acquired by the acquiring with the opening degree.

In an aspect, the acquiring may acquire opening degrees of the opening degree variable valve in relation to all of the plurality of sequential processing steps.

The acquiring may acquire the opening degrees of the opening degree variable valve in relation to all of the plurality of sequential processing steps in the same order as the plurality of sequential processing steps.

The acquiring may be performed just before the executing of a first processing step among the plurality of sequential processing steps.

The processing condition may include at least one of a kind of the processing gas, a flow rate of the processing gas, and a processing temperature.

The acquiring may acquire the opening degree of the opening degree variable valve by using an operation table of a PID control operation.

The acquiring may acquire the opening degree of the opening degree variable valve at a point of time when a pressure within the processing container falls within a predetermined pressure range around the target pressure value as a center value, for a predetermined time.

The predetermined time may range from 1 sec to 30 sec.

The opening degree variable valve may be provided in the exhaust system.

Another aspect of the present disclosure is to provide a processing apparatus that processes an object to be processed by using a processing gas in a plurality of sequential processing steps. The processing apparatus includes: a processing container configured to perform a process on the object to be processed; a gas supply system configured to supply at least a processing gas to the processing container; an exhaust system configured to exhaust inside of the processing container; an opening degree variable valve configured to adjust an exhaust amount of the exhaust system; and a control unit configured to acquire in advance an opening degree of the opening degree variable valve corresponding to a target pressure value within the processing container under a predetermined processing condition for at least one of the plurality of sequential processing steps, and execute the at least one of the plurality of sequential processing steps for which the opening degree has been acquired with the opening degree.

The present disclosure provides a processing method which may allow the pressure within the processing container to reach a required pressure value or a required pressure range within a relatively short time.

Hereinafter, exemplary embodiments of the present disclosure will be described with reference to the accompanying drawings.

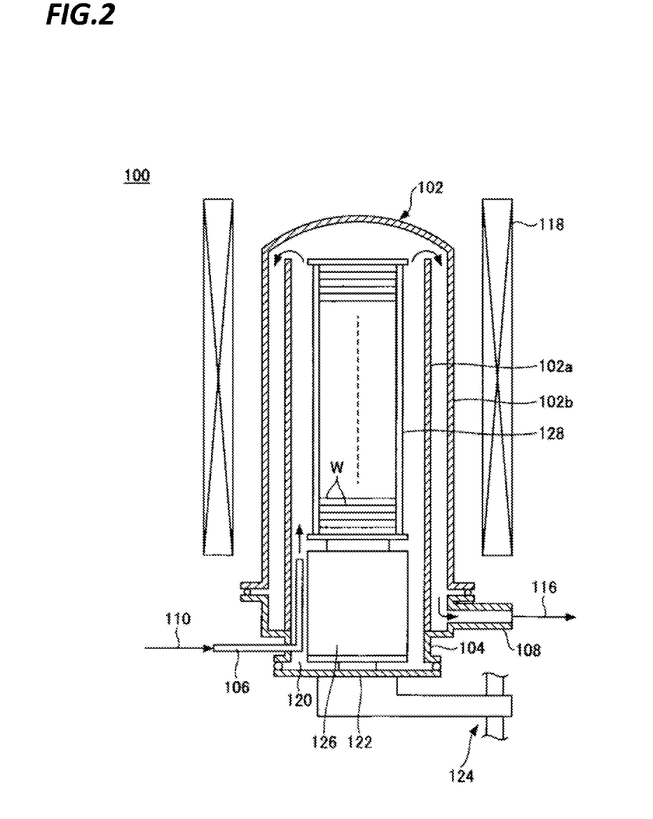

Descriptions will be made for the present exemplary embodiment using a vertical type heat processing apparatus to be described below as illustrated in FIG. 2. The vertical type heat processing apparatus is configured to perform various processings on the object to be processed (e.g., semiconductor wafers W), such as, for example, an atomic layer deposition (ALD) processing, a thermal chemical vapor deposition (CVD) processing, and an oxidation processing. However, the present disclosure is not limited thereto, but may also be applied to, for example, a plasma CVD deposition apparatus, a microwave plasma processing apparatus, and a plasma ion implantation deposition apparatus.

The present disclosure may be applied to any process having a plurality of sequential processing steps. The present disclosure may be appropriately applied to a process in which a target pressure value is changed between adjacent processing steps in the plurality of sequential processing steps.

Among the processes including the plurality of sequential processing steps, the ALD process is a deposition method in which the pressure needs to be adjusted to a required target pressure value more quickly with higher accuracy than other semiconductor processing processes. Specifically, descriptions will be made on a case where a processing gas is introduced into a processing gas container to perform a film deposition in a processing step, and in the following processing step, the processing gas is exhausted from the inside of the processing gas container through introduction of a purge gas. In transition from one processing step to the following processing step, the processing time until the processing gas is exhausted after the purge gas is introduced into the processing container is generally required to be set as about several seconds. Accordingly, the processing method of the present exemplary embodiment may be employed in order to allow the pressure of the container to reach a predetermined pressure range within a short time.

(Processing Apparatus)

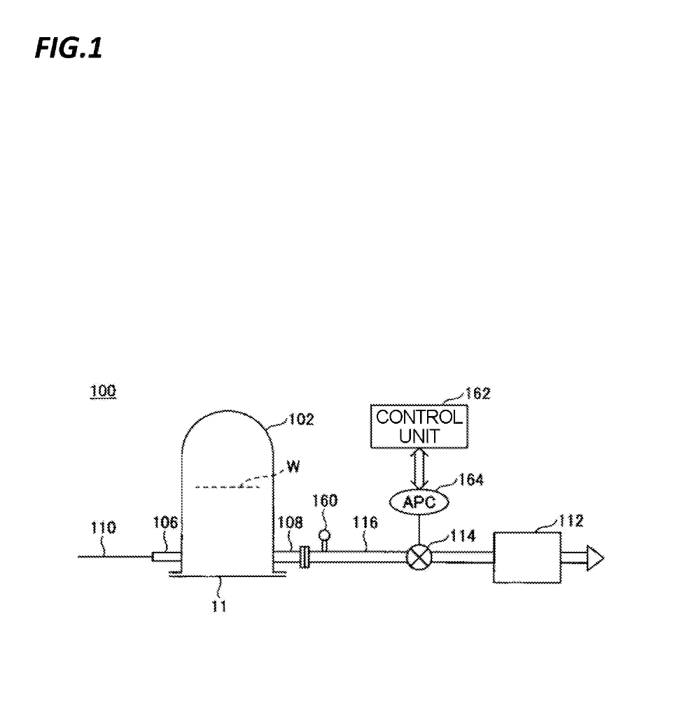

FIG. 1 illustrates a schematic configuration view of a processing apparatus according to an exemplary embodiment of the present disclosure. FIG. 2 illustrates a schematic configuration view of the vicinity of a processing container of the processing apparatus of FIG. 1.

A processing apparatus 100 according to the present exemplary embodiment includes, for example, a processing container 102 having a vertical direction as a longitudinal direction, and is made of, for example, quartz. As illustrated in FIG. 2, the processing container 102 is configured in a double-tube structure that includes, for example, a cylindrical inner tube 102a, and an outer tube 102b with a ceiling which is concentrically disposed outside the inner tube 102a.

The processing container 102 includes a lower portion which is airtightly maintained by a manifold 104 made of, for example, stainless steel. The manifold 104 may be fixed on a base plate (not illustrated).

The manifold 104 includes a gas introducing unit 106 configured to introduce a processing gas or a purge gas such as, for example, an inert gas (e.g., N₂ gas) into the processing container 102, and a gas exhaustion unit 108 configured to exhaust the inside of the processing container 102. Although one gas introducing unit 106 is provided in the configuration illustrated in FIG. 1, the present disclosure is not limited thereto. Another configuration that includes a plurality of gas introducing units 106 according to, for example, the number of gas species to be used may be employed as well.

A pipe 110 serving as a gas feeding path configured to introduce the above described various kinds of gases, is connected to the gas introducing unit 106. A pipe 116 serving as a vacuum exhaust path including, for example, a vacuum pump 112 or an opening degree variable valve 114, is connected to the gas exhaustion unit 108. The vacuum pump 112 is configured to perform the vacuum control of the inside of the processing container 102.

Around the processing container 102, for example, a cylindrical heater 118 is provided to perform a heat control of the processing container 102 to a predetermined temperature.

A furnace throat 120 is formed in the lower portion of the manifold 104, and is provided with a disk shaped cover 122 made of, for example, stainless steel. The cover 122 is provided to be movable up and down by an elevating mechanism 124, and to be capable of sealing the furnace throat 120.

A heat insulating cylinder 126 made of, for example, quartz is provided on the cover 122. A wafer boat 128 made of, for example, quartz is mounted on the heat insulating cylinder 126. In the wafer boat 128, for example, about 25 to 150 sheets of wafers W are horizontally held at predetermined intervals in multi stages.

The wafer boat 128 is carried into the processing container 102 when the cover 122 is moved up by the elevating mechanism 124, and is carried out of the inside of the processing container 102 to a loading area at the lower side when the cover 122 is moved down.

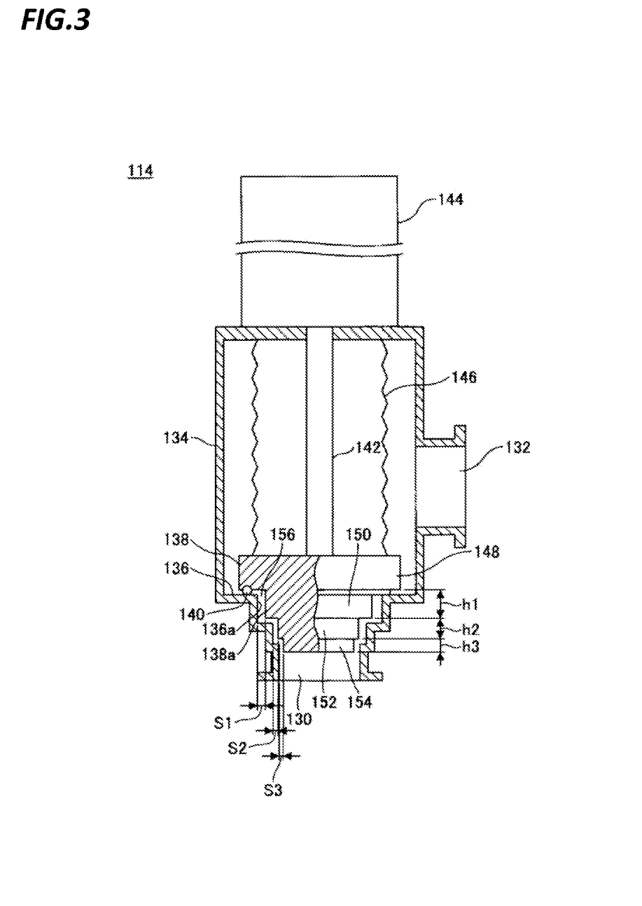

As described above, the pipe 116 of the vacuum exhaust system is provided with the opening degree variable valve 114 which is configured to perform the control of opening/closing and pressure. FIG. 3 illustrates a schematic configuration view of the vicinity of the opening degree variable valve 114 of FIG. 1.

As illustrated in FIG. 3, the opening degree variable valve 114 includes an angle valve-shaped valve chest 134 which has an inlet 130 at the bottom thereof, and an outlet 132 at the side portion thereof. Within the valve chest 134, a planar valve seat 136 is formed which is expanded from the inner side of the inlet 130 to the radial outside. At the same time, a valve element 138 is provided such that seating or movement of the valve element 138 on or away from the valve seat 136 may be adjustable.

The valve chest 134 and the valve element 138 are made of a heat resistant and corrosion resistant material such as, for example, stainless steel.

An O ring 140 made of, for example, a fluoro rubber is provided, as a sealing member, on the portion of the valve element 138 which is attached or detached to/from the valve seat 136.

A valve rod 142 is vertically provided at the center of the top of the valve element 138. A valve element driving unit 144 is provided at the top of the valve chest 134, which adjusts seating or movement of the valve element 138 on or away from the valve seat 136 via the valve rod 142 that penetrates the upper portion of the valve chest 134.

As the valve element driving unit 144, a driving unit such as, for example, a pulse motor or a screw feeding mechanism may be used.

A bellows 146 is interposed by, for example, welding between the upper end of the valve element 138 and the upper end within the valve chest 134 to cover the periphery of the valve rod 142. The bellows 146 may seal a ring-shaped penetration portion of the valve rod 142 while allowing movement of the valve element 138.

The valve element 138 is formed in a circular shape such that its diameter is reduced stepwise downwardly. In order to correspond to the shape of the valve element 138, the shape of the valve seat 136 at the inlet 130 side also has a stepwise reducing diameter.

The bottom surface of an upper maximum diameter portion 148 of the valve element 138 is formed to face the top portion of the valve seat 136 and is provided with the O ring 140. The diameter reducing portion of the valve element 138 is formed in a plurality of stages below the upper maximum diameter portion 148, for example, in three stages of an upper stage 150, a middle stage 152 and a lower stage 154.

On diameter reducing portions of the valve element 138 and the valve seat 136, peripheral wall portions 138a and 136a are formed facing each other in a direction perpendicular to a movement direction of the valve element 138. The pair of peripheral wall portions 138a and 136a is formed such that the diameters thereof are increased stepwise in the opening movement direction of the valve element 138.

A fine adjustment gap 156 is formed between the peripheral wall portions 138a and 136a. The heights h1, h2, and h3 of the upper stage 150, the middle stage 152 and the lower stage 154 are configured such that h1>h2>h3. The widths s1, s2, and s3 of the gap 156 at the upper stage 150, the middle stage 152 and the lower stage 154 are configured such that s1≧s2≧s3.

The conductance of vacuum pressure in the gap 156 is inversely proportional to the cross-sectional area of the gap 156, and proportional to the distance dimension of the gap 156. When the valve element 138 is opened gradually from the opening position, the pressure is first dominated by the gap 156 of the lower stage 154 with a small cross-sectional area, then by the gap 156 of the middle stage 152, and finally by the gap 156 of the upper stage 150. Through this configuration, the pressure control may be easily carried out in a pressure range with a relatively low vacuum.

In the pipe 116, a pressure gauge 160 configured to measure the pressure within the processing container 102 is provided between the processing container 102 and the opening degree variable valve 114, so as to measure the internal pressure within the processing container 102 frequently.

A control unit 162 is provided at outside of the processing container 102. The control unit 162 includes, for example, an operation processing unit, a storage unit and a display unit (not illustrated). The operation processing unit is, for example, a computer having a central processing unit (CPU). The storage unit is, for example, a computer readable recording medium constituted by a hard disk, which stores a program that causes the operation processing unit to perform various processings. The display unit is constituted by, for example, a computer screen. The operation processing unit reads out the program stored in the storage unit, and performs the processing method to be described below according to the program.

The pressure within the processing container 102 which is measured by the pressure gauge 160, is transmitted to the control unit 162 frequently. An APC 164 is equipped in the opening degree variable valve 114, and a control signal from the control unit 162 is transmitted to the APC 164 such that the opening degree of the opening degree variable valve 114 may be controlled.

For example, an operation table for PID operation control is provided in the control unit 162. In the control unit 162, in the acquisition process to be described later, based on the pressure value of the pressure gauge 160 (the pressure within the processing container 102), the opening degree variable valve 114 provided with the APC 164 may be controlled using the operation table. By controlling the opening degree variable valve 114, the pressure value within the processing container 102 may be controlled to be the internal pressure (target pressure value) of the processing container 102 under the processing conditions such as, for example, the kind of a processing gas, the flow rate of the processing gas and the processing temperature.

(Processing Method)

Hereinafter, descriptions will be made on the processing method according to the present exemplary embodiment in the processing apparatus configured as described above. More specifically, hereinafter, descriptions will be made on a pressure control inside the processing container 102 in a case where a plurality of sequential processing steps is performed on an object to be processed within the processing container 102.

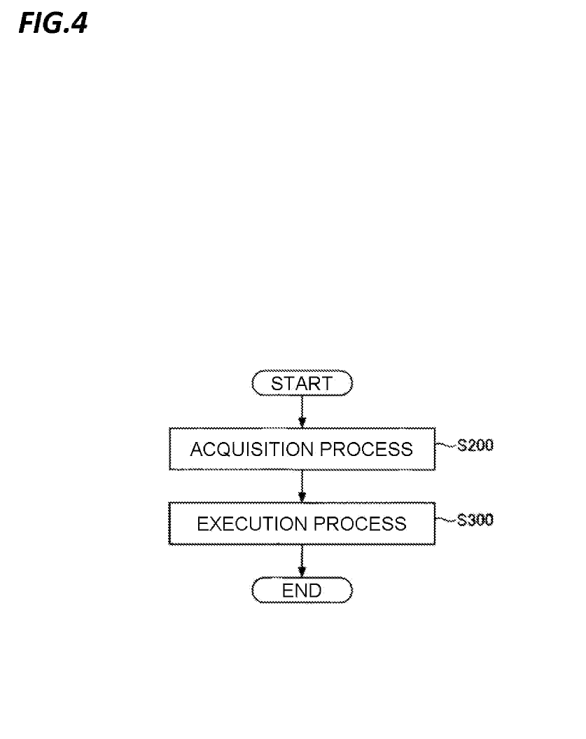

FIG. 4 illustrates a flow chart of a processing method according to an exemplary embodiment of the present disclosure.

The processing method according to the present disclosure includes: an acquisition process S200 for acquiring an opening degree of the opening degree variable valve corresponding to a target pressure value within the processing container under a predetermined processing condition for at least one of a plurality of sequential processing steps; and an execution process S300 for executing the at least one of the plurality of sequential processing steps for which the opening degree has been acquired by the acquisition process with the opening degree.

Specific examples of the respective processing steps will be described with reference to the drawings.

[Acquisition Process]

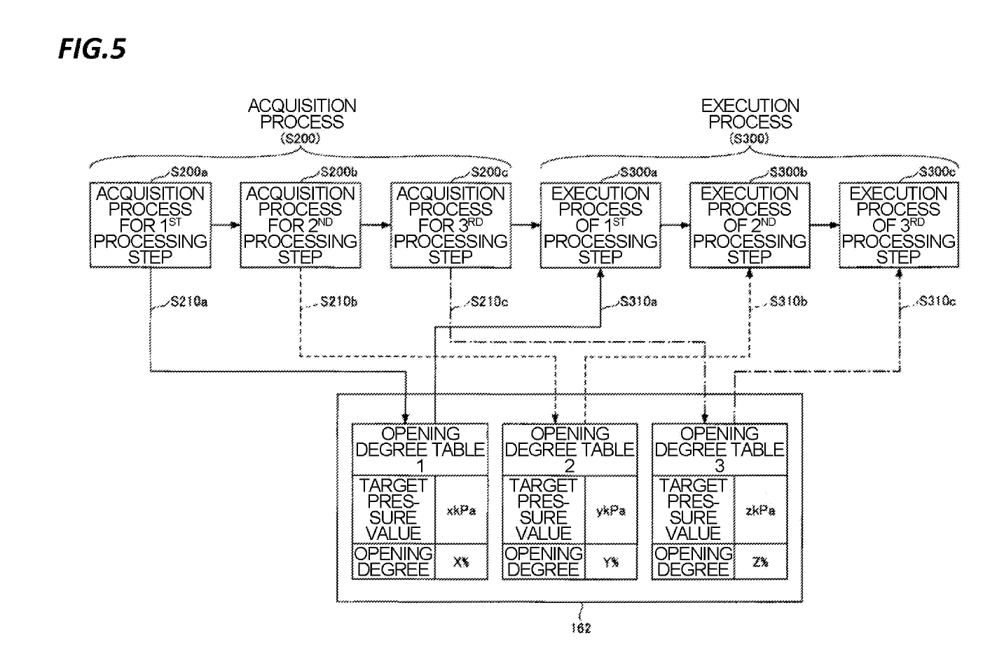

FIG. 5 illustrates a schematic view for explaining the processing method according to the present disclosure. In the present exemplary embodiment, descriptions will be made on, for example, a deposition method on an object to be processed by three sequential processing steps including a first processing step for performing a processing with a first target pressure value, a second processing step for performing a processing with a second target pressure value after the first processing step, and a third processing step for performing a processing with a third target pressure value after the second processing step. However, the processing method of the present disclosure may include two processing steps or four or more processing steps as long as the method includes a plurality of sequential processing steps.

First, in a step prior to an acquisition process, a target pressure value for each of a first processing step, a second processing step and a third processing step is determined The target pressure value is a condition for obtaining a desired film, and is previously determined by a person skilled in the art together with at least one condition among processing conditions, such as, the kind of a processing gas, the flow rate of the processing gas and the processing temperature.

The target pressure value and the processing condition for each processing step are input to a control unit 162. The input target pressure value is transmitted from the control unit 162 to an APC 164 such that the control of an opening degree variable valve 114, that is, pressure control inside a processing container 102 is performed first in relation to a first target pressure value (S200a). The pressure control is performed by using an operation table such as, for example, a PID control operation under the same processing conditions as those in the first processing step. “The same processing conditions as those in the first processing step” indicates that the processing conditions are the same as the kind of the processing gas, the flow rate of the processing gas and the processing temperature in the first processing step.

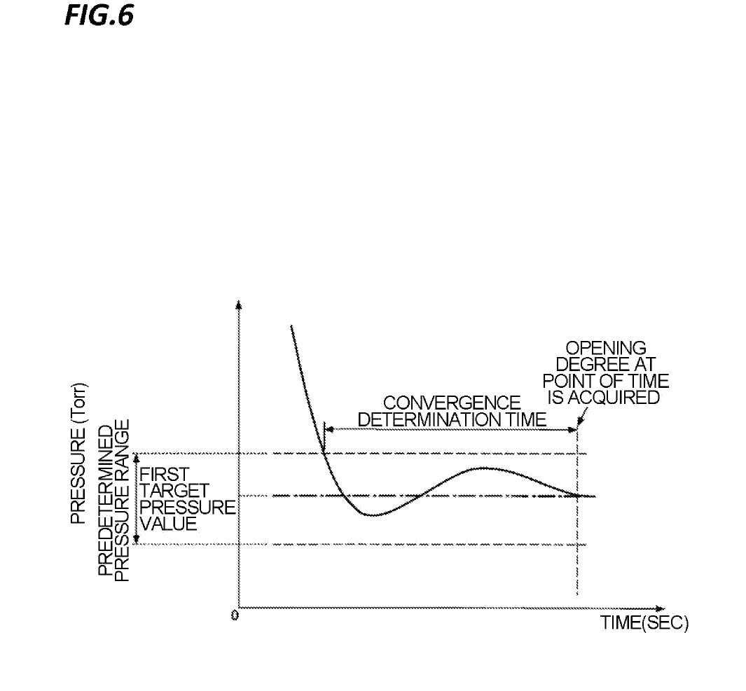

FIG. 6 illustrates a schematic view for explaining an acquisition process according to the present disclosure. In FIG. 6, the horizontal axis represents time, the vertical axis represents pressure, and the solid line represents a pressure value within the processing container 102. In the present exemplary embodiment, descriptions will be made on a method of acquiring an opening degree corresponding to a first target pressure value represented by the one-dotted chain line in FIG. 6.

The pressure control, as illustrated in FIG. 6, is completed at a point of time when the pressure within the processing container 102 falls within a predetermined pressure range around the first target pressure value, for a predetermined time (convergence determination time). The completion of the pressure control is transmitted to the control unit 162 as a control completion signal. The opening degree of the opening degree variable valve 114 at the point of time is stored as the opening degree Table 1, together with the first target pressure value, in, for example, a storage unit within the control unit 162 (S210a).

The above described “predetermined time” is also called a convergence determination time, and may be appropriately set by a person skilled in the art. As the convergence determination time increases, a pressure of the processing container 102 comes close to an actual opening degree of the opening degree variable valve corresponding to the target pressure value, but a time required for determination is prolonged. In general, the convergence determination time ranges from about 1 sec to 60 sec, and may ranges from about 1 sec to 30 sec, or from about 10 sec to 60 sec.

Subsequently, after the control completion signal is transmitted to the control unit 162, the control of the opening degree variable valve 114 is performed in relation to a second target pressure value (S200b). The pressure control is performed by using an operation table such as, for example, a PID control operation under the same processing conditions as those in the second processing step.

As in the first target pressure value, the pressure control for the second target pressure value is also completed at a point of time when the pressure within the processing container 102 falls within a predetermined pressure range around the second target pressure value for a predetermined time. The completion of the pressure control is transmitted to the control unit 162 as a control completion signal. The opening degree of the opening degree variable valve 114 at the point of time is stored as opening degree Table 2, together with the second target pressure value, in, for example, a storage unit (not illustrated) within the control unit 162 (S210b).

Subsequently, after the control completion signal is transmitted to the control unit 162, the control of the opening degree variable valve 114 is performed in relation to a third target pressure value (S200c). The pressure control is performed by using an operation table such as, for example, a PID control operation under the same processing conditions as those in the third processing step.

As in the first target pressure value and the second target pressure value, the pressure control for the third target pressure value is also completed at a point of time when the pressure within the processing container 102 falls within a predetermined pressure range around the third target pressure value for a predetermined time. The completion of the pressure control is transmitted to the control unit 162 as a control completion signal. The opening degree of the opening degree variable valve 114 at the point of time is stored as the opening degree Table 3, together with the third target pressure value, in, for example, a storage unit (not illustrated) within the control unit 162 (S210c).

In the above described configuration according to the present exemplary embodiment, the storage unit is provided in the control unit 162, but may be provided in the APC 164 or other components.

In the above described configuration of the present exemplary embodiment, the acquisition process is performed for all of the plurality of sequential processing steps, but the present disclosure is not limited thereto. In another configuration, the acquisition process may be performed for at least one of the plurality of sequential processing steps, and, for example, for a processing step which needs to induce the pressure in the preceding processing step to a target pressure value (target pressure range) within a short time.

The acquisition process may acquire an opening degree of an opening degree variable valve for each processing step in the same order as the order of processing steps to be executed in the execution process.

[Execution Process]

Subsequently, actual processing steps are executed (S300a, S300b and S300c) with reference to the opening degrees of the opening degree variable valve 114 acquired in the acquisition process from opening degree Tables 1 to 3 (S310a, S310b and S310c).

The execution process may be performed immediately after the acquisition process. That is, the acquisition process may be performed just before the execution process within the same recipe as that of the execution process. In the same recipe, the acquisition process is performed, and subsequently, the execution process is performed so that almost the same processing conditions as those in the processing steps to be executed in the execution process may be reproduced in the acquisition process.

The performance of the acquisition process and the execution process in the same recipe indicates specifically that before the execution process, the acquisition process is performed for determining a target pressure value for each of a plurality of sequential processing steps and inputting the determined target pressure value into the control unit 162.

Before an actual deposition processing in the execution process, an inert gas is introduced into the processing container 102 first from a gas introducing unit 106, and the inside of the processing container 102 is exhausted through a gas exhaustion unit 108 so that the inside of the processing container 102 is replaced with the inert gas. Then, a cover 122 is opened so that a wafer boat 128 accommodating the object to be processed (wafers W) is carried into the processing container 102, together with a heat insulating cylinder 126.

Subsequently, while the inert gas is blocked from being introduced, the processing container 102 is exhausted from the gas exhaustion unit 108 so as to perform a vacuum replacement. Here, in order to suppress particles from winding up, a slow vacuum is performed up to, for example, about 10 Torr.

Subsequently, under the previously determined processing conditions of the first processing step, a first execution process is initiated. Here, as for the opening degree of the opening degree variable valve 114, the opening degree for the first processing step, which has been acquired in the acquisition process, is used. After the first execution process is completed, a second execution process is initiated under the previously determined processing conditions of the second processing step. Here, as for the opening degree of the opening degree variable valve 114, the opening degree for the second processing step, which has been acquired in the acquisition process, is used. After the second execution process is completed, a third execution process is initiated under the previously determined processing conditions of the third processing step. Here, as for the opening degree of the opening degree variable valve 114, the opening degree for the third processing step, which has been acquired in the acquisition process, is used.

After the execution processes for all of the processing steps are completed, vacuum of the inside of the processing container 102 is replaced with an inert gas so that the inside of the processing container 102 may be returned to a normal pressure. Then, the cover 122 is opened downward so as to carry out the wafer boat 128 from the inside of the processing container 102.

As described above, in the processing method of the present exemplary embodiment, in a state where a target pressure value for each of a plurality of sequential processing steps is determined according to, for example, the gas species of a processing gas corresponding to each processing step, the gas flow rate or the temperature, an opening degree of an opening degree variable valve corresponding to the target pressure value is acquired in advance by an operation table. When the actual processing steps are executed by the acquired opening degree, it is possible to reach the determined pressure range within a relatively short time. Accordingly, the stabilization of the internal pressure within the processing container may be performed within a relatively short time at the time of shift of processing steps.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A processing method that processes an object to be processed within a processing container connected to a gas supply system, an exhaust system and an opening degree variable valve by using a processing gas in a plurality of sequential processing steps, the method comprising:
acquiring an opening degree of the opening degree variable valve corresponding to a target pressure value within the processing container under a predetermined processing condition for at least one of the plurality of sequential processing steps; and executing the at least one of the plurality of sequential processing steps for which the opening degree has been acquired by the acquiring with the opening degree.

2. The processing method of claim 1, wherein the acquiring acquires opening degrees of the opening degree variable valve in relation to all of the plurality of sequential processing steps.

3. The processing method of claim 2, wherein the acquiring acquires the opening degrees of the opening degree variable valve in relation to all of the plurality of sequential processing steps in the same order as the plurality of sequential processing steps.

4. The processing method of claim 1, wherein the acquiring is performed just before the executing of a first processing step among the plurality of sequential processing steps.

5. The processing method of claim 1, wherein the processing condition includes at least one of a kind of the processing gas, a flow rate of the processing gas, and a processing temperature.

6. The processing method of claim 1, wherein the acquiring acquires the opening degree of the opening degree variable valve by using an operation table of a PID control operation.

7. The processing method of claim 1, wherein the acquiring acquires the opening degree of the opening degree variable valve at a point of time when a pressure within the processing container falls within a predetermined pressure range around the target pressure value as a center value for a predetermined time.

8. The processing method of claim 7, wherein the predetermined time ranges from 1 sec to 30 sec.

9. The processing method of claim 1, wherein the opening degree variable valve is provided in the exhaust system.

10. A processing apparatus that processes an object to be processed by using a processing gas in a plurality of sequential processing steps, the processing apparatus comprises:
a processing container configured to perform a process on the object to be processed;
a gas supply system configured to supply at least a processing gas to the processing container;
an exhaust system configured to exhaust inside of the processing container;
an opening degree variable valve configured to adjust an exhaust amount of the exhaust system; and
a control unit configured to acquire in advance an opening degree of the opening degree variable valve corresponding to a target pressure value within the processing container under a predetermined processing condition for at least one of the plurality of sequential processing steps, and execute the at least one of the plurality of sequential processing steps for which the opening degree has been acquired with the opening degree.
